(19) United States
(12) Patent Application Publication
(10) Pub. No.: US 2023/0072705 A1
(43) Pub. Date: Mar. 9, 2023

(54) ANTIMICROBIAL NANOLAMINATES USING VAPOR DEPOSITED METHODS

(71) Applicant: Prerna Goradia, Mumbai (IN)

(72) Inventor: Prerna Goradia, Mumbai (IN)

(21) Appl. No.: 17/988,895

(22) Filed: Nov. 17, 2022

Related U.S. Application Data
(63) Continuation of application No. PCT/IN2022/050576, filed on Jun. 23, 2022.

(30) Foreign Application Priority Data
Aug. 30, 2021 (IN) 202121039247

(51) Int. Cl. C23C 16/455; C23C 16/40; C23C 16/50; C23C 16/44; C23C 16/448

(52) U.S. Cl. CPC C23C 16/45527; C23C 16/408; C23C 16/45502; C23C 16/50; C23C 16/4417; C23C 16/4481

(57) ABSTRACT

Methods for making nanolaminates using Vapor Deposited methods such as Chemical Vapor Deposition and Physical Vapor Deposition, which can be applied on various surfaces, including glass, the soft polymeric material, or surgical instruments, as well as synthetic, composite, and organic materials. Methods of manufacturing nanolaminates by employing sequential surface reactions, wherein the antimicrobial coatings are provided by employing an Atomic Layer Deposition (ALD) process, thermal spray and or aerosol assisted deposition.

### RELATED APPLICATIONS

This application claims the benefit under 35 U.S.C. § 120, and is a continuation, of co-pending International Application PCT/IN2022/050576, filed Jun. 23, 2022 and designating the US, which claims priority to Indian Application 202121039247, filed Aug. 30, 2021 such IN Application also being claimed priority to under 35 U.S.C. § 119. These IN and International applications are incorporated by reference herein in their entireties.

### BACKGROUND

Antimicrobial surface coatings work to suppress the growth of bacteria and harmful microorganisms and stop the spread of microbes. In addition to deterring bacteria, germs and molds, the coating also minimizes stains and degradation of plastic on the surfaces they are applied to. These antimicrobial agents come in a variety of types like chlorhexidine, ammonium compounds, and silver compounds and so on. Though these coatings provide microbial resistance but there had been drawbacks with the migration of these antimicrobials into the article due to uneven deposition or corrosion of the article.

To overcome these drawbacks, thin film deposition methods such as physical vapor deposition (PVD) and the chemical vapor deposition (CVD) have been the popular deposition methods used in a wide range of applications. These coatings can be used to protect the surface displays from scratches or environmental exposure, by providing specific degree of reflectivity on glass or building layers of metallization on wafers.

References have been made to the following literature:

Research publication by Silvia Gonzalez demonstrates that the nano structuring and surface functionalization processes constitute a promising route to fabricate novel functional materials exhibiting highly efficient antimicrobial features. It has been shown that the appropriated association of TiO2 layer and Ag nanoparticle coatings over the nanostructured 316L stainless steel exhibited an excellent antimicrobial behavior for all biofilms examined. These functional coatings were grown on the nanostructured substrate by following electroless process, electrochemical deposition, and atomic layer deposition (ALD) techniques. The coatings in the prior art involve wet and dry techniques which might not be controlled on the film morphology and thickness (González, A. S.; Riego, A.; Vega, V.; García, J.; Galié, S.; Gutiérrez del Río, I.; Martínez de Yuso, M. d. V.; Villar, C. J.; Lombó F.; De la Prida, V. M. Functional Antimicrobial Surface Coatings Deposited onto Nanostructured 316L Food-Grade Stainless Steel. Nanomaterials 2021, 11, 1055. doi.org/10.3390/nano11041055).

Research publication by Eun K. Seof demonstrates an atomic layer deposition of TiO2 thin films on self-assembled monolayers of ω-functionalized alkanethiolates. The TiO2 thin films were grown on OH-terminated alkanethiolate monolayer-coated gold by atomic layer deposition at 100° C. The atomic layer deposition of the TiO2 thin films is self-controlled and extremely linear relative to the number of cycles. Selective deposition of the TiO2 thin film using atomic layer deposition was accomplished with patterned self-assembled monolayers as templates. Microcontact printing was done to prepare the patterned monolayers of the alkanethiolates on gold substrates. The selective atomic layer deposition is because the TiO2 thin film is selectively deposited only on the regions exposing OH-terminated alkanethiolate monolayers of the gold substrates, because the regions covered with CH3-terminated monolayers do not have any functional group to react with precursors. Self-assembled monolayers in the prior art are flimsy layers and growing an ALD layer on top of this may compromise the robustness of the coating (Seo, Eun K et al. “Atomic Layer Deposition of Titanium Oxide on Self-Assembled-Monolayer-Coated Gold.” Chemistry of Materials 16 (2004): 1878-1883).

CA2987938A relates to a nano-engineered coating for cathode active materials, anode active materials, and solid-state electrolyte materials for reducing corrosion and enhancing cycle life of a battery, and processes for applying the disclosed coating. The protective coating is obtained by atomic layer deposition (ALD) or molecular layer deposition (MLD) only.

U.S. Ser. No. 10/821,619B2 relates to a razor blade having one or more coatings formed by the atomic layer deposition (ALD) process, the formed coatings being uniform, conformal, and dense. The coatings may be on an entire surface of a blade flank, and at least a portion or an entire surface of a blade body.

U.S. Pat. No. 10,195,602B2 relates to a photocatalytic system having enhanced photo efficiency/photonic efficacy that includes a thin nucleation material coated on a substrate. The nucleation material enhances lattice matching for a subsequently deposited photocatalytic active material.

This background provides a useful baseline or starting point from which to better understand some example embodiments discussed below. Except for any clearly identified third-party subject matter, likely separately submitted, this Background and any figures are by the Inventor(s), created for purposes of this application. Nothing in this application is necessarily known or represented as prior art.

### SUMMARY

The principal object of the present invention is to provide thin film coatings using vapor deposited methods and specifically atomic layer deposition and physical vapor deposition, which can be applied on various surfaces, including glass, the soft polymeric materials and or hard surfaces such as surgical instruments/medical devices, as well as synthetic and organic materials.

The present invention attempts to overcome the problems faced in the prior art and discloses thin film deposition coatings suitable for use on a variety of substrate articles and equipment. These coatings besides providing even surface depositions, give large area coverage, and unique properties. Specifically, the present invention relates to a method of coating substrates by vapor deposition based antimicrobial coatings. It provides stable coatings on the sensitive surfaces such as glass or medical equipment wherein besides providing antimicrobial properties, these coatings have application in other areas which exploit properties such as optical, mechanical, electrical and others. Further, the thickness and the composition of the coatings can also be controlled,

The present invention discloses vapor deposited coatings using atomic layer deposition and physical vapor deposition on surfaces while not altering the characteristics of the articles and method of preparing the same. The invention further discloses a method of forming antimicrobial coatings wherein the first coating is of a first material and the second coating is of a second material. The second coating in the sequential process may be deposited on top surface of the first coating, wherein the first and second coating layers may be similar or different, and the coating is deposited using an ALD process and/or combinations with other chemical and physical vapor deposition methods.

In accordance with the embodiments of the present invention, the invention discloses a method of making nanolaminates by vapor deposition process, the method including the steps:

i) depositing conformal atomic layers on a substrate placed on a chuck by transferring the substrate in a first chamber for chemical vapor deposition, comprising: a) flowing a carrier gas and a purge gas in the chamber; b) setting temperature of the chuck and a heater in the chamber, followed by stabilizing the chamber; c) flowing the carrier gas and purge gas at a flow rate designated for coating the atomic layer; d) passivating surface of the substrate by pulsing a precursor 1 for a designated amount of pulse time, followed by removing excess precursor 1 by purging with carrier gas; e) pulsing a precursor 2 for a designated amount of pulse time to complete the surface reaction in the first chamber, followed by removing excess precursor 2 by purging with carrier gas; wherein steps (d) and (e) forming one monolayer are repeated multiple times as per the required thickness of the atomic layer; and e) flowing the purge and carrier gases for purging the first chamber for removing the by-products;

ii) transferring the substrate to a second chamber for coating a metal based layer by physical vapor deposition on the substrate comprising: a) transferring a metal containing material to be deposited on the substrate from a condensed phase in the target to a vapor phase by sputtering and evaporation, wherein the target is the source material to be deposited; b) supersaturation of the vapor phase in an inert atmosphere to promote the condensation of the metal containing layer on the substrate; and c) heating of substrate containing nanolaminate by thermal treatment under inert atmosphere as per the desired property of nanolaminate required; wherein steps (i) and (ii) are carried out at least once in any order sequentially based on the surface of the substrate and the property of nanolaminate required.

In another embodiment the present invention discloses a method where chemical vapor deposition is used for depositing at least a layer of material selected from a group comprising tungsten, titanium, molybdenum, silicon, tantalum, nickel, zinc, copper, gold, chromium, yttria, and their oxides, nitrides and other inorganic and organometallic derivatives and combinations thereof. Besides, the precursor for layering in the chemical vapor deposition is selected from a group comprising organic compounds such as metal alkoxides, metal alkyls, metal diketonites, metal amindinates, metal carbonyls, metal chlorides, organometallics, organic-inorganic materials, and combinations thereof. At least one of the precursor is further selected from a group such as Mo, Ta and Ti deposited from respective pentachlorides; Ni, Mo, and W deposited at low temperatures from respective carbonyl precursors; Tetrakis (dimethyl amino) titanium (TDMAT), diethyl zinc and a range of materials that can form metal oxides such as ZnO, SnO2, ZrO2, Y2O3; the noble metals Pt, Ag, Au and the metal nitrides; aliphatic or aromatic organic precursors consisting of molecules with —OH, —COOH, —NH2, —CONH2, —CHO, —COCl, —SH, —CNO, —CN, alkenes, functional groups, but not limited to and combinations thereof.

In yet another embodiment the present invention discloses a method where at least one carrier gas and purge gas are selected from a group of inert gases comprising argon, nitrogen, helium, and combinations thereof and the flow rate of the gases is in the range of 20 to 200 sccm. Besides, the heater temperature in the chamber is in the range 16-250° C.

In still another embodiment the chuck on which the substrate is placed is heated to the desired temperature in the thermal treatment to aid the deposition process and yield a conformal coating of nanolaminates. The chamber body is made of at least one selected from the group comprising aluminum, stainless steel, and combinations thereof and the chamber can be further selected from an ultra-high vacuum chamber or an atmospheric chamber and is stabilized by maintaining the temperature and pressure. The inert atmosphere is maintained using at least a gas selected from a group comprising helium, argon, nitrogen, and combinations thereof. The pulse for precursor is given for a time ranging from mS to 5 seconds and at least one of the coatings has a thickness ranging from about 0.1 nm to about 200 nm.

In another preferred embodiment the present invention discloses a method where physical vapor deposition is for depositing layers of metal containing materials selected from a group comprising titanium, titanium nitrate, tantalum, tantalum nitrate, compounds of metals such as copper, silver, gold, and combinations thereof and derivatives of nitrides, oxide, carbide, boride but not limited to. In PVD processes, the substrate temperature is substantially lower than the melting temperature of the target material, making it feasible to coat temperature-sensitive materials. Examples of commonly used PVD processes include thermal evaporative deposition, ion plating, pulsed laser deposition, and sputter deposition.

In yet another embodiment the substrate for coating is glass, soft polymeric materials, hard surfaces such as surgical instruments/medical devices, powder, synthetic and organic materials, or combinations thereof. Further, the transfer of substrate from one chamber to another involves minimum queue time and exposure to ambient conditions, with maintenance of an inert and/or a vacuum environment.

In another preferred embodiment the coating for substrate by vapor deposition method is selected from a group comprising chemical vapor deposition (CVD) such as atomic layer deposition (ALD), spatial ALD, Molecular layer deposition (MLD), plasma assisted ALD, self-assembled monolayers (SAM), aerosol assisted deposition (AACVD) and physical vapor deposition (PVD) such as thermal spray, sputtering, thermal evaporation, patterning of layers with lithography and combinations thereof. Further, coating by chemical vapor deposition of substrates is done with at least one selected from aerosol assisted CVD (AACVD) or deposition with self-assembled monolayers (SAM) with organic molecules using dip, spray to electrostatically charge the surface of the nanolaminates. To impart a texture to help in repelling microbes, patterning of layers with lithography is done as the final step before the deposition of the last layer.

In another embodiment the nanolaminates/substrates coated by the method of the present invention, based on the optical, mechanical, electrical, and magnetic properties of the coatings has applications in a variety of areas such as semiconductor, energy storage, MEMS, life sciences and drug delivery, but not limited to.

### BRIEF DESCRIPTIONS OF THE DRAWINGS

Example embodiments will become more apparent by describing, in detail, the attached drawings, wherein like elements are represented by like reference numerals, which are given by way of illustration only and thus do not limit the example embodiments herein.

FIG. 1 illustrates the schematic representation of the method of making nanolaminates by vapor deposition process, in accordance with an embodiment of the present invention;

FIG. 2 illustrates the schematic representation of the ALD Process Parameters for thermal deposition of ZnO at 250° C. and 451 cycles, in accordance with an embodiment of the present invention; and

FIG. 3 illustrates the combination of wafer stacks (samples), in accordance with an embodiment of the present invention.

### DETAILED DESCRIPTION

Because this is a patent document, general broad rules of construction should be applied when reading it. Everything described and shown in this document is an example of subject matter falling within the scope of the claims, appended below. Any specific structural and functional details disclosed herein are merely for purposes of describing how to make and use examples. Several different embodiments and methods not specifically disclosed herein may fall within the claim scope; as such, the claims may be embodied in many alternate forms and should not be construed as limited to only examples set forth herein.

Membership terms like “comprises,” “includes,” “has,” or “with” reflect the presence of stated features, characteristics, steps, operations, elements, and/or components, but do not themselves preclude the presence or addition of one or more other features, characteristics, steps, operations, elements, components, and/or groups thereof. Rather, exclusive modifiers like “only” or “singular” may preclude presence or addition of other subject matter in modified terms. The use of permissive terms like “may” or “can” reflect optionality such that modified terms are not necessarily present, but absence of permissive terms does not reflect compulsion. In listing items in example embodiments, conjunctions, and inclusive terms like “and,” “with,” and “or” include all combinations of one or more of the listed items without exclusion. The use of “etc.” is defined as “et cetera” and indicates the inclusion of all other elements belonging to the same group of the preceding items, in any “and/or” combination(s). Modifiers “first,” “second,” “another,” etc. may be used herein to describe various items, but they do not confine modified items to any order. These terms are used only to distinguish one element from another; where there are “second” or higher ordinals, there merely must be that many number of elements, without necessarily any difference or other relationship among those elements.

When an element is related, such as by being “connected,” “coupled,” “on,” “attached,” “fixed,” etc., to another element, it can be directly connected to the other element, or intervening elements may be present. In contrast, when an element is referred to as being “directly connected,” “directly coupled,” etc. to another element, there are no intervening elements present. Other words used to describe the relationship between elements should be interpreted in a like fashion (e.g., “between” versus “directly between,” “adjacent” versus “directly adjacent,” etc.).

As used herein, singular forms like “a,” “an,” and “the” are intended to include both the singular and plural forms, unless the language explicitly indicates otherwise. Indefinite articles like “a” and “an” introduce or refer to any modified term, both previously-introduced and not, while definite articles like “the” refer to the same previously-introduced term. Relative terms such as “almost” or “more” and terms of degree such as “approximately” or “substantially” reflect 10% variance in modified values or, where understood by the skilled artisan in the technological context, the full range of imprecision that still achieves functionality of modified terms. Precision and non-variance are expressed by contrary terms like “exactly.”

The structures and operations discussed below may occur out of the order described and/or noted in the figures. For example, two operations and/or figures shown in succession may in fact be executed concurrently or may be executed in the reverse order, depending upon the functionality/acts involved. Similarly, individual operations within example methods described below may be executed repetitively, individually or sequentially, so as to provide looping or other series of operations aside from exact operations described below. It should be presumed that any embodiment or method having features and functionality described below, in any workable combination, falls within the scope of example embodiments.

The inventor has recognized that despite availability of a widespread variety of antimicrobial agents, they have a limited durability and activity.

The present invention is antimicrobial nanolaminates and methods of making the same. In contrast to the present invention, the few example embodiments and example methods discussed below illustrate just a subset of the variety of different configurations that can be used as and/or in connection with the present invention.

The present invention relates to method of manufacturing nanolaminates by employing sequential surface reactions, wherein the antimicrobial coatings are provided by employing vapor deposited techniques such as chemical vapor deposition using atomic layer deposition (ALD) and physical vapor deposition on the substrate surfaces. ALD can be counted as the most advanced version of the traditional CVD process and has several advantages compared to the others, including conformal coatings, large area coverage, and unique physical and optical properties. It is also possible to molecularly dope and form nanocomposites/nanolaminates with organic materials. It provides stable coatings on sensitive surfaces such as glass or medical equipment wherein besides antimicrobial other favorable properties such as optical, mechanical, electrical semiconductor, energy storage, MEMS, life sciences and drug delivery among a host of others. Further, the thickness and the composition of the coatings can also be minutely controlled.

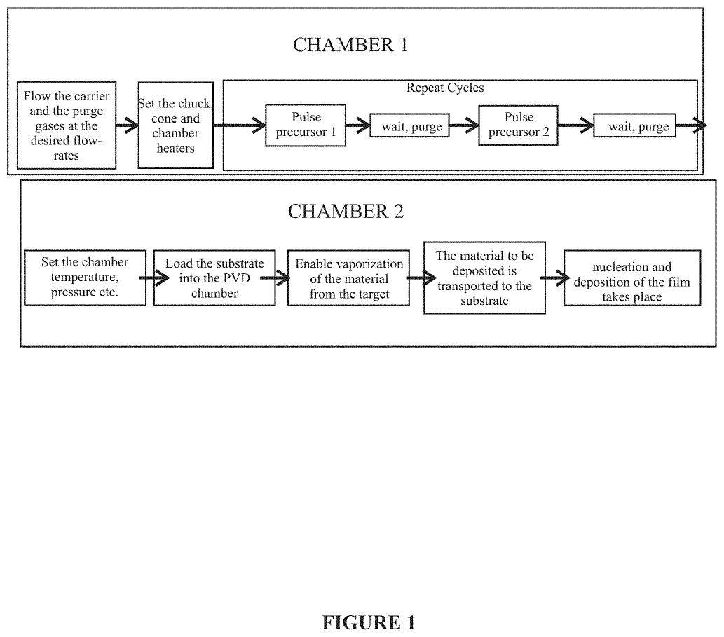

Reference may be made to FIG. 1 illustrating the schematic representation of the method of making nanolaminates by vapor deposition process, in accordance with an embodiment of the present invention. The vapor deposition process comprises of coating nanolaminates by a combination of chemical vapor deposition and physical vapor deposition steps. In an embodiment of this process, a substrate, which may be glass, soft polymeric materials, hard surfaces such as surgical instruments/medical devices, powder, synthetic and organic materials or combinations thereof, is coated for the first coating of conformal atomic layers in a first chamber by chemical vapor deposition (CVD), by following the following step of flowing the carrier gas and purge gas, setting the chuck, cone and chamber heaters and stabilizing the chamber. In particular, the chuck on which the substrate is placed is heated to the desired temperature in the thermal treatment to aid the deposition process and yield a conformal coating of nanolaminates. Moreover, the stabilization of chamber is enabled by maintaining the temperature and pressure. Further, in an embodiment of the present invention, at least one of the carrier gas and the purge gas maybe selected from a group of inert gases comprising argon, nitrogen, helium and combinations thereof and the flow rate of the gases is in the range of 20 to 200 sccm. Further, the temperature of the chuck and the heater is set to 16 to 250° C. followed by stabilizing the chamber. Further, the surface of the substrate is passivated by pulsing a precursor 1 for a designated amount of pulse time and thereafter removing any excess precursor 1 by purging with carrier gas. In an embodiment of the present invention, the pulse time could range between 0.1 milliseconds to 5 seconds. Subsequent to pulsing precursor 1 and waiting for 5 seconds thereafter, a precursor 2 is pulsed for a designated amount of pulse time and thereafter removing any excess precursor 2 by purging with carrier gas. In an embodiment of the present invention, the pulse time could range between 0.1 milliseconds to 5 seconds. Any further coating could be carried out subsequently after waiting for 5 seconds of the last cycle of coating and purging. Further, the steps of pulsing precursor 1 and precursor 2 may be repeated several times as per the required thickness of the conformal atomic layer. In an embodiment of the present invention the precursors for layering may be selected from a group comprising organic compounds such as metal alkoxides, metal alkyls, metal diketonites, metal amindinates, metal carbonyls, metal chlorides, organometallics, organic-inorganic materials and combinations thereof. In another embodiment of the present invention, at least one of the precursor is further selected from a group comprising at least one of Mo, Ta and Ti deposited from respective pentachlorides; Ni, Mo, and W deposited at low temperatures from respective carbonyl precursors; Tetrakis (dimethyl amino) titanium (TDMAT), diethyl zinc and a range of materials that can form metal oxides such as Zn1−xSnxOy, ZrO2, Y2O3; the noble metals Pt, Ag, Au and the metal nitrides; aliphatic or aromatic organic precursors consisting of molecules with —OH, —COOH, —NH2, —CONH2, —CHO, —COCl, —SH, —CNO, —CN, alkenes, functional groups, and oxidizer such as oxygen, ozone, water, air and combinations and or a reducer such as hydrogen gas or a plasma excited reactant and combinations thereof. In an embodiment of the present invention, the steps may be repeated between 100-1000 times as per the thickness of the layer. In an embodiment of the present invention, the chemical vapor deposition process may be used for depositing on the substrate at least a layer of material selected from a group comprising tungsten, titanium, molybdenum, silicon, tantalum, nickel, zinc, copper, gold, chromium, yttria, and their oxides, nitrides and other inorganic and organometallic derivatives and combinations thereof.

Once the conformal atomic layers have been deposited, the substrate is transferred to a second chamber for a second coating of one or more metal-based layers by physical vapor deposition (PVD). In an embodiment of the present invention, the physical vapor deposition process could enable depositing layers of metal containing materials selected from a group comprising titanium, titanium nitrate, tantalum, tantalum nitrate, compounds of metals such as copper, silver, gold and combinations thereof and derivatives of nitrides, oxide, carbide, boride. The subsequent steps include transferring a metal containing material to be deposited on the substrate from a condensed phases in the target to a vapor phase by way of sputtering and evaporation. Sputtering includes bombardment of target by energetic species selected from a group of inert gas such as argon, nitrogen to achieve a thin film vapor-phase deposition on the substrate. Also, evaporation of the target is conducted by resistive heating it to its evaporation point using electrical energy to achieve the vapor-phase species which nucleates and deposits on the substrate. Further steps include setting the chamber temperature and pressure, followed by loading the substrate into the chamber, enabling vaporization of the material from the target, and transporting the material to be deposited to the substrate, where further nucleation and deposition of the film takes place. To facilitate supersaturation of vapor phase, an inert atmosphere is provided using at least a gas selected from a group comprising helium, argon, nitrogen and combinations thereof, which promotes condensation of the metal containing layer on the substrate. Supersaturation includes covering of almost all active sites on the substrate by a precursor of the material to make a fully reacted layer on the surface. The precursor that is to be administered enters the second chamber in the vapor phase and gets deposited by reacting with the substrate functionalities or the layer from the earlier half-reactions. Further, the substrate is heated under inert atmosphere to a temperature as per the desired property of the nanolaminate that is required. The process is repeated for the coating of the similar or different material in an alternate or sequential manner. Further, while the process has been explained with reference to a specific embodiment where the process of chemical vapor deposition precedes the process of physical vapor deposition, it may be noted that the two deposition processes could be carried out in any sequence one after the other. Thus, in another embodiment of the present invention, the physical vapor deposition process could precede the chemical vapor deposition process based on the type and property of coatings required. In an embodiment of the present invention, the resulting thickness of at least one of the conformal atomic layers and metal-based layers could be ranging between about 0.1 nm to about 200 nm. Further, transfer of the substrate from one chamber to another involves minimum queue time and exposure to ambient conditions, with maintenance of an inert and/or a vacuum environment. Furthermore, at least one coating includes a plurality of monolayers, wherein a first layer of material and a second layer of material for the coating have same or different characteristics and the coating is deposited using a chemical vapor deposition process or physical vapor deposition process. In addition, the coatings for substrates by vapor Deposited method is selected from a group comprising chemical vapor deposition (CVD) such as atomic layer deposition (ALD), spatial ALD, Molecular layer deposition (MLD), self-assembled monolayers (SAM), aerosol assisted deposition (AACVD) and physical vapor deposition (PVD) such as thermal spray, sputtering, thermal evaporation, patterning of layers with lithography and combinations thereof. Moreover, the coating by chemical vapor deposition of substrates is done with at least one selected from aerosol assisted CVD (AACVD) or deposition with self-assembled monolayers (SAM) with organic molecules using dip, spray to electrostatically charge the surface of the nanolaminates.

Further, in an embodiment of the present invention, body of the first and the second chamber is made of at least one selected from the group comprising aluminum, stainless steel and combinations thereof. In another embodiment of the present invention, the first and the second chamber are selected from an ultra-high vacuum chamber or an atmospheric chamber.

Additionally, the process includes patterning of layers with lithography being carried out before the deposition of the final layer to impart a texture to help in repelling microbes.

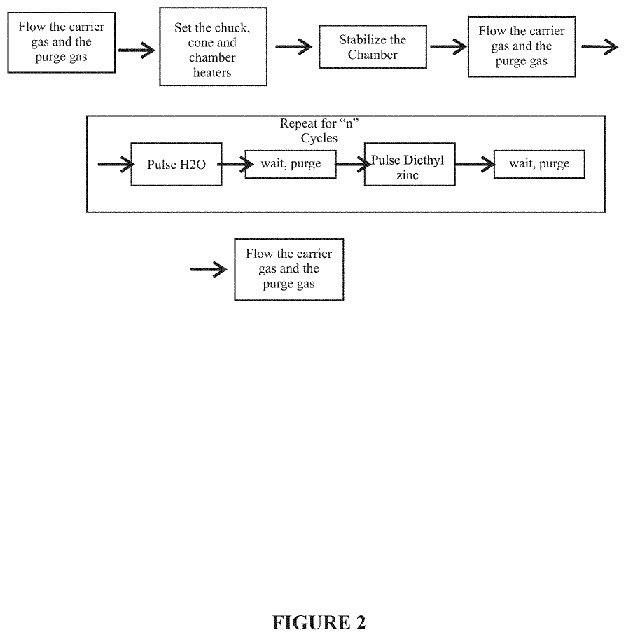

Atomic Layer Deposition (ALD) is a special type of the chemical vapor deposition (CVD) technique. For generating the desired material, the technique comprises of introducing the gaseous reactants (precursors) into the reaction chamber via chemical surface reactions, wherein the precursors are pulsed alternately, one at a time, and separated by inert gas purging in order to avoid gas phase reactions. Once the saturation is reached after the whole surface is covered by the monolayer of first gas, the excess gas is pumped away, and a second gas is introduced that gets condensed and is further chemisorbed on top of the first layer. The excess second gas is pumped away and the whole process can be repeated to deposit a second monolayer of the same or different material. This sequence can be repeated as many times as necessary to deposit the desired total coating thickness. This successive, self-terminated surface reaction of the reactants result in controlled layering of the desired material. The unique self-limiting growth mechanism results in perfect conformality and thickness uniformity of the film even on complicated 3D structures (FIG. 2).

Reference may be made to FIG. 2 illustrating the schematic representation of the ALD Process Parameters for thermal deposition of ZnO at 250° C. and 451 cycles, in accordance with an embodiment of the present invention. In this process the coating is done by the ALD process comprising the steps: a) flowing the carrier gas and purge gas, wherein the purge gas is at 5-60 sccm and carrier gas at 20-200 sccm; b) Setting the chuck, cone and chamber heaters at 100 to 250° C.; c) Stabilizing the chamber for 10 min; d) Flowing the carrier gas at 60 sccm and the purge gas at 200 sccm and waiting for 60 seconds; e) Pulsing oxygen-containing precursors, preferably water for 0.06 seconds and waiting for 5 seconds, followed by pulsing the precursor Diethyl zinc for 0.1 second into the vacuum chamber and subsequently waiting for 5 seconds for the coating; wherein step e is repeated 1000-1500 times as per the thickness of the layer; f) Flowing the carrier gas at 5 sccm and the purge gas at 15 sccm. The process is further repeated for the second coating of the similar or different material in an alternate or sequential manner.

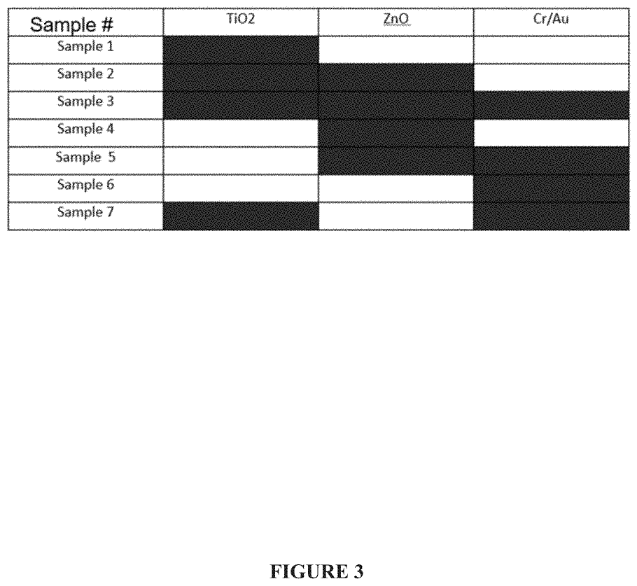

Reference may be made to FIG. 3 illustrating the combination of wafer stacks (samples), in accordance with an embodiment of the present invention. The table describes the details of the samples prepared using nanolaminates containing layers of ALD (CVD) and thermal evaporation (PVD);

Thickness measurements of the TiO2 and ZnO were verified using ellipsometry, in accordance with an embodiment of the present invention. Ellipsometry is done to measure the thickness of the film, where, the measurement is performed by polarizing an incident light beam, reflecting it off a smooth sample surface at a large oblique angle and then re-polarizing the light beam prior to its intensity measurement.

Thickness measurements of Cr/Au were verified using a Dektak profilometer, in accordance with an embodiment of the present invention. Dektak profilometer measures height or trench depth on a surface. In this surface contact measurement technique, a very low force stylus is dragged across a surface and leveling of data is done in the software and cursor locations and step heights are provided in the form of print out.

In accordance with the embodiments of the present invention, the invention provides a method of making nanolaminates by vapor deposition process, the method comprising the steps:

i) depositing conformal atomic layers on a substrate placed on a chuck by transferring the substrate in a first chamber for chemical vapor deposition, comprising: a) flowing a carrier gas and a purge gas in the chamber; b) setting temperature of the chuck and a heater in the chamber, followed by stabilizing the chamber; c) flowing the carrier gas and purge gas at a flow rate designated for coating the atomic layer; d) passivating surface of the substrate by pulsing a precursor 1 for a designated amount of pulse time, followed by removing excess precursor 1 by purging with carrier gas; e) pulsing a precursor 2 for a designated amount of pulse time to complete the surface reaction in the first chamber, followed by removing excess precursor 2 by purging with carrier gas; wherein steps (d) and (e) forming one monolayer are repeated multiple times as per the required thickness of the atomic layer; and e) flowing the purge and carrier gases for purging the first chamber for removing the by-products;

ii) transferring the substrate to a second chamber for coating a metal based layer by physical vapor deposition on the substrate comprising: a) transferring a metal containing material to be deposited on the substrate from a condensed phase in the target to a vapor phase by sputtering and evaporation, wherein the target is the source material to be deposited; b) supersaturation of the vapor phase in an inert atmosphere to promote the condensation of the metal containing layer on the substrate; and c) heating of substrate containing nanolaminate by thermal treatment under inert atmosphere as per the desired property of nanolaminate required; wherein steps (i) and (ii) are carried out at least once in any order sequentially based on the surface of the substrate and the property of nanolaminate required.

In accordance with the embodiments of the present invention, the invention discloses a method where chemical vapor deposition is for depositing at least a layer of material selected from a group comprising tungsten, titanium, molybdenum, silicon, tantalum, nickel, zinc, copper, gold, chromium, yttria, and their oxides, nitrides and other inorganic and organometallic derivatives and combinations thereof. Further, the precursor for layering in the chemical vapor deposition is selected from a group comprising organic compounds such as metal alkoxides, metal alkyls, metal diketonites, metal amindinates, metal carbonyls, metal chlorides, organometallics, organic-inorganic materials and combinations thereof. At least one of the precursor for the coating is further selected from a group such as Mo, Ta and Ti deposited from respective pentachlorides; Ni, Mo, and W deposited at low temperatures from respective carbonyl precursors; Tetrakis (dimethyl amino) titanium (TDMAT), diethyl zinc and a range of materials that can form metal oxides such as ZnO—SnO2, ZrO2, Y2O3; the noble metals Pt, Ag, Au and the metal nitrides; aliphatic or aromatic organic precursors consisting of molecules with —OH, —COOH, —NH2, —CONH2, —CHO, —COCl, —SH, —CNO, —CN, alkenes, functional groups, but not limited to and combinations thereof. Precursor 2 generally reacts with adsorbed precursor 1 to complete the half reaction for the deposition of one atomic layer and may be an oxidizer such as oxygen, ozone, water, air and combinations and or a reducer such as hydrogen gas or a plasma excited reactant but not limited to. Precursor 1 is the organometallic and the precursor 2 is the reactant that completes the reaction to make it an oxide, nitride etc.

In another embodiment of the present invention, the invention discloses a method where at least one carrier gas and purge gas are selected from a group of inert gases comprising argon, nitrogen, helium and combinations thereof and the flow rate of the gas is in the range of 20 to 200 sccm. Further, the heater temperature in the chamber is in the range 16-250° C. The chamber body in which the reaction takes place, is made of at least one selected from the group comprising aluminum, stainless steel and combinations thereof. The chamber can be selected from an ultra-high vacuum chamber or an atmospheric chamber and is stabilized by maintaining the temperature and pressure.

In accordance with the embodiments of the present invention, the invention discloses a method where the pulse for the precursors is given for a time ranging from 0.1 mS to 5 seconds. The thickness of the conformal atomic layer coatings is in the range of 0.1 nm to 200 nm.

Further, to aid the deposition process and yield a conformal coating of nanolaminates, the chuck on which the substrate is placed is heated to the desired temperature. The precursors may also be heated to generate enough vapor pressure for delivery. In certain cases where the temperature is to be kept low the plasma assisted ALD can also be used, where plasma-assisted atomic layer deposition (ALD) is an energy-enhanced method for the synthesis of thin films at low temperatures in which plasma is employed during one step of the cyclic deposition process. The invention also discloses a method wherein spatial ALD may also be one of the methods for coating, wherein the substrate is moved in space below a special gas curtain, and the precursor gases are separated by inert gas curtains. In this way, large substrates such as display screens and large number of multiple small substrates such as medical devices can be coated efficiently. Therefore, the spatial ALD separates the two precursors in space, rather than in time. The substrate is moved back and forth between the two precursor gases to replicate the sequential exposures. This eliminates the evacuation and purge steps that make traditional ALD slow. Spatial ALD can operate in atmospheric conditions which make it very practical. At the same time, it can produce thin-film layers of materials that are dense and pinhole-free. Also, it can deposit thin films at low temperatures (typically <350° C.) and at the same time can be couple orders of magnitude faster than conventional ALD and is scalable as it can deal with large substrates.

In another embodiment, the invention discloses a method of antimicrobial coatings wherein self-assembled monolayers such as thiols, phosphonic acids, silanes may be used for further enhancement of antimicrobial properties and other features for medical devices, steel substrates, glass displays. For example, the molecule Triethoxy-1H,1H,2H,2H-tridecafluoro-n-octylsilane was used to increase the hydrophobicity of the surface. Aerosol assisted CVD may also be applied to administer molecules especially low vapor pressure molecules to the surfaces. The anti-bacterial, anti-viral and anti-fungal property with the films deposited is expected to be far better because of the unique combination of materials. Further, molecular layer deposition (MLD) and atomic layer deposition (ALD) are similar, but ALD is generally used for inorganic coatings, whereas the precursor chemistry in MLD can use small, organic molecules that have binding groups on both terminals. Therefore, the organic layers are deposited in a process similar to polymerization. MLD can help in deposition of organic-inorganic materials. The backbone of the organic precursors can be aliphatic, or aromatic. The organic precursors usually consist of molecules with —OH, —COOH, —NH2, —CONH2, —CHO, —COCl, —SH, —CNO, —CN, alkenes, etc. functional groups. The bifunctional nature of the precursors is essential for continuous film growth as one group reacts with the surface and the other one with the second precursor. Many organometallic precursors can be for the deposition of hybrid organic-inorganic MLD layers. for example, zinc alkyls such as Zn(CH2CH3)2, diethylzinc can react with diols such as ethylene glycol or trimethylaluminium can react with ethylene glycol. Besides, metal alkyls of Mg and Mn such as Mg(Cp)2 and Mn(Cp)2 where Cp is the cyclopentadienyl ligand could be considered, metal alkyls based on magnesium (Mg) and manganese (Mn) that react with diols, can possibly be used. Other possible metal alkyls are ferrocene, Fe(Cp)2, nickelocene, Ni(Cp)2 and cobaltocene, Co(Cp)2, but not limited to.

In accordance with the embodiments of the present invention, the invention discloses a method of coating nanolaminates where physical vapor deposition is for depositing layers of metal containing materials selected from a group comprising titanium, titanium nitrate, tantalum, tantalum nitrate, compounds of metals such as copper, silver, gold and combinations thereof and derivatives of nitrides, oxide, carbide, boride but not limited to.

Physical vapor deposition (PVD) refers to a variety of vacuum deposition methods to generate a vapor, in the form of atoms, molecules, or ions, of the coating material supplied from a target. They are then transported to and deposited on the substrate surface, resulting in coating formation. In PVD processes, the substrate temperature is substantially lower than the melting temperature of the target material, making it feasible to coat temperature-sensitive materials. Examples of commonly used PVD processes include thermal evaporative deposition, ion plating, pulsed laser deposition, and sputter deposition. As compared to evaporative deposition, sputtering is more suitable for target materials that are difficult to deposit by evaporation, such as ceramics and refractory metals. In addition, coatings prepared by sputtering usually have a better bonding strength to the substrate than those deposited by evaporation.

Thermal evaporation basically uses a resistive heat source to evaporate a solid material in a vacuum environment to form a thin film. The material is heated in a high vacuum chamber until vapor pressure is produced. The evaporated material, or vapor stream, traverses the vacuum chamber with thermal energy and coats the substrate. Sputtering sources often employ magnetrons that utilize strong electric and magnetic fields to direct charged plasma on the sputter target. The sputter gas is typically an inert gas such as argon. The argon ions created as a result of these collisions lead to the good deposition. Further, evaporation of the target is conducted by resistive heating to achieve the vapor-phase deposition on the substrate. In this method, the target is heated to its evaporation point using electrical energy. The vapor phase species then reaches the substrate where it nucleates to form the layer. Further, supersaturation comprises covering of almost all active sites on the substrate by a precursor of the material to make a fully reacted layer on the surface. The precursor that is to be administered enters the chamber in the vapor phase and gets deposited by reacting with the substrate functionalities or the layer from the earlier half-reactions.

In yet another embodiment of the present invention, the transfer of substrate from one chamber to another involves minimum queue time and exposure to ambient conditions, with maintenance of an inert and/or a vacuum environment.

In another preferred embodiment, the substrate for coating is glass, soft polymeric materials, and hard surfaces such as surgical instruments/medical devices, powder, synthetic and organic materials or combinations thereof.

In still another embodiment, the invention discloses a method where at least one coating comprises a plurality of monolayers, wherein a first layer of material and a second layer of material for the coating have same or different characteristics and the coating is deposited using a chemical vapor deposition process or physical vapor deposition process. Further, the coatings for substrates by Vapor Deposited method is selected from a group comprising chemical vapor deposition (CVD) such as atomic layer deposition (ALD), spatial ALD, Molecular layer deposition (MLD), self-assembled monolayers (SAM), aerosol assisted deposition (AACVD) and physical vapor deposition (PVD) such as thermal spray, sputtering, thermal evaporation, patterning of layers with lithography and combinations thereof. Coating by chemical vapor deposition of substrates is done with at least one selected from aerosol assisted CVD (AACVD) or deposition with self-assembled monolayers (SAM) with organic molecules using dip, spray to electrostatically charge the surface of the nanolaminates. To impart a texture to help in repelling microbes, patterning of layers with lithography is done as the final step before the deposition of the last layer.

In another embodiment of the present invention, the invention discloses a method where the nanolaminates based on the optical, mechanical, electrical, and magnetic properties of the coatings has applications in a variety of areas such as semiconductor, energy storage, MEMS, life sciences and drug delivery, but not limited to.

Examples: The need for laminates: Laminates ensure good antimicrobial performance as compared to single films and when the films are very thin, the lower layers influence the overall antimicrobial activity.

Example 1: In this example nanolaminates with several quartz wafers, with different combinations of the ALD layering were prepared as depicted in FIG. 3. The figure describes the details of the samples prepared using nanolaminates containing layers of ALD (CVD) and thermal evaporation (PVD). The thickness of the TiO2 and ZnO was verified using ellipsometry and that of the Cr/Au was verified using a Dektak profilometer. The verification of the thickness of the TiO2 and ZnO layers was done respectively (Tables 1 & 2).

TABLE 1
Validation using ellipsometry 5-point measurement

| Point | RI | Thickness (nm) | Goodness of Fit |
|---|---|---|---|
| 1 | 2.318 | 39.26 | 2.82 |
| 2 | | 38.26 | 2.88 |
| 3 | | 40.41 | 2.97 |
| 4 | | 39.10 | 2.83 |
| 5 | | 38.71 | 2.73 |
| Average | | 39.148 | |

The average thickness of the deposited TiO2 layer turned out to be around 40 nm.

TABLE 2
Validation using ellipsometry 5-point measurement

| Point | RI | Thickness (nm) | Goodness of Fit |
|---|---|---|---|
| 1 | 1.956 | 65.46 | 11.031 |
| 2 | | 65.48 | 11.68 |
| 3 | | 64.85 | 11.42 |
| 4 | | 65.23 | 10.50 |
| 5 | | 65.69 | 11.49 |
| Average | | 65.352 | |

The average thickness of the deposited ZnO layer turned out to be around 65 nm.

Example 2: Further as gold is known to have exceptional antimicrobial properties, layers of chromium (Cr) (for adhesion) and Gold (Au) were deposited onto the samples to evaluate this (Table 3). As explained, thermal evaporation methodology involved a resistive heat source to evaporate a solid material in a vacuum environment to form a thin film. The material is heated in a high vacuum chamber until vapor pressure is produced. Thermal evaporation deposits both metals and nonmetals, including aluminum, chrome, gold, indium, and many others. Complex applications include the co-deposition of several components and can be achieved by carefully controlling the temperature of individual crucibles. In this deposition the rate of deposition was monitored using quartz crystal rate sensor. The samples were cleaned using piranha solutions and the rest of the parameters are presented below.

TABLE 3
Process Parameters for the deposition of the Cr/Au
in the thermal evaporator tool

| | |
|---|---|
| No of Samples | 3 |
| Sample History | Quartz/Piranha/TiO2 |
| | Quartz/Piranha |
| | Si |
| | (For thickness measurement) |
| Metal Deposited Cr/Au | Cr/Au |
| Thickness Deposited | 10/100 |
| (Cr/Au) nm | |
| Roughing Vacuum (mbar) | 4.0 E-2 |
| High Vacuum (mbar) | 4.7 E-6 |
| Quartz Crystal Life (h) | 6.96 |
| Current For Cr (mA) | 67 |
| Rate For Cr (nm/Min) | 0.2 |
| Current For Au (mA) | 3.46 |
| Rate For Au (nm/Min) | 0.9 to 1.0 |

The thickness of the resultant film measured using a Dektat profilometer was recorded to be an average of 96 nm. Here the layers of the metal were deposited using the thermal evaporator tool, the important point being the combination of vapor-phase metal with other photocatalytic materials as an important aspect of the invention.

TABLE 4
Thickness of the layers using Dektak Profilometer

| Point | Thickness (nm) |
|---|---|
| 1 | 88.9 |
| 2 | 97.2 |
| 3 | 102.8 |
| Average | 96.3 |

Example 3: Microbiological studies: Further the antimicrobial ability of the described stacks was studied by using various standard methods. ASTM-2149 test was done for checking the anti-microbial activity of the coatings. 10 μl vol. of approx. 1-5×104 CFU/ml of cell culture was applied on to the glass quart which was placed individually into separate sterile plates. The glass quart was left into incubator at 37 deg. for 10 min for drying. After drying, this glass quart was put into the 100 ml phosphate buffer and each sample was vertex for 1 hour contact time, then it was removed, and it was added into the Neutralizer solution. It was placed into different sterile petri dishes and neutralizing media was poured into each quart. Again, each sample was vertex for 2 min to facilitate the release of the carrier load from the sample surface into neutralizing broth then the analysis was done. Their controls were plated with SCDA by taking 1 ml volume. The plates were incubated at 37 deg. for 48 hrs. After incubation the readings were taken with the help of colony counter and results were recorded. (Table 5)

TABLE 5
Neutralizer Test

| | | | Test | % Recovery |
|---|---|---|---|---|
| Test | Particulars | Control | Results | of control |
| Test A | Sample + | 91 | 83 | 91.20 |
| Neutralizer | DENA + | | | |
| Effectiveness | Organisms | | | |
| Test B | DENA + | | 87 | 95.60 |
| Neutralizer | Organisms | | | |
| toxicity | | | | |
| Test C | Phosphate | | 89 | 97.80 |
| Test Organisms | buffer + | | | |
| Viability | organisms | | | |

From the results it was inferred that the test sample glass quart when compared with Lab Glass slide SAMPLE as reference sample showed antimicrobial activity against E. coli bacteria and showed percent reduction in cell count as shown in Table 6.

TABLE 6
Analysis performance: Initial Cell Concentration:
8.1 × 104 cfu/ml

| | | | | Antibacterial |
|---|---|---|---|---|
| | | | | activity |
| | Count | % | Log | Observed/ |
| Sample | observed | Reduction | value | Not Observed |
| Sample-1 | 0 | 99.99 | 0 | Observed |
| Sample -2 | 0 | 99.99 | 0 | Observed |
| Sample -3 | 20 | 99.85 | 1.30 | Observed |
| Sample -4 | 20 | 99.85 | 1.30 | Observed |
| Sample -5 | 40 | 99.70 | 1.60 | Observed |
| Sample -6 | 150 | 98.90 | 2.17 | Observed |
| Sample -7 | 50 | 99.63 | 1.69 | Observed |
| Sample -8 | 4400 | 67.88 | 3.64 | Observed |
| (Control | | | | |
| sample) | | | | |
| Lab Glass | 13700 | — | — | — |
| slide | | | | |

Example 4: Another test was done to check the antimicrobial activity of glass quart against E. coli organism. 10 μl vol. of approx. 1-5×106 CFU/ml of cell culture was applied on to glass quart which was placed individually into separate sterile plates and the above glass quart was left into incubator 37 deg. for 10 min for drying. After drying, this glass quart was put into the 100 ml phosphate buffer for 1 hour contact time, then removed it and added it into neutralizer solution along with microbes. It was placed into different sterile petri dishes and neutralizing media was poured into each quart. Each sample was vortexed for 2 min to facilitate the release of the carrier load from the sample surface into neutralizing broth then the analysis was performed. Their controls were plated with SCDA by taking 1 ml volume. Incubated the plates for 37 deg. 48 hrs. After incubation took out the readings with the help of colony counter and the results were interpreted. (Table 7)

TABLE 7
Neutralizer test:

| | | | Test | % Recovery |
|---|---|---|---|---|
| Test | Particulars | Control | Results | of control |
| Test A | Sample + | 89 | 87 | 97.75 |
| Neutralizer | DENA + | | | |
| Effectiveness | Organisms | | | |
| Test B | DENA + | | 84 | 94.38 |
| Neutralizer | Organisms | | | |
| toxicity | | | | |
| Test C | Phosphate | | 81 | 91.01 |
| Test Organisms | buffer + | | | |
| Viability | organisms | | | |

It was observed that the test samples Glass quart when compared with Lab Glass slide SAMPLE as reference sample showed antimicrobial activity against E. coli bacteria. (Table 8)

TABLE 8
Results of antimicrobial activity of Glass quart:
Initial Cell Concentration:
2.4 × 102 cfu/ml

| | | | | Antibacterial |
|---|---|---|---|---|
| | | | | activity |
| | | | | Observed/ |
| | Count | % | Log | Not |
| Sample | observed | Reduction | value | Observed |
| Sample-1 | 1 | 99.99 | 0 | Observed |
| Sample -2 | 1 | 99.99 | 0 | Observed |
| Sample -3 | 2 | 99.98 | 0.30 | Observed |
| Sample -4 | 12 | 99.93 | 1.07 | Observed |
| Sample -5 | 7 | 99.96 | 0.84 | Observed |
| Sample -6 | 6 | 99.96 | 0.78 | Observed |
| Sample -7 | 2 | 99.98 | 0.30 | Observed |
| Sample -8 | 6 | 99.96 | 0.78 | Observed |
| Control sample | | | | |
| Lab Glass slide | 18000 | — | 4.26 | — |

The coating of the present invention had several unique mechanisms of action compared with single layer coatings and the ZnO and TiO2 layers together provided an extremely synergistic effect. The polarity of the surfaces was also studied, with the results presented in the table below (Table 9). The TiO2 and ZnO yielded a more hydrophobic surface, but the effects of the overall film-stack also affected the layers on top. Further, the spectrophotometric profile was also measured and the sample 4 showed a good transmittance.

TABLE 9
Data showing the polarity of surface

| Sr no | Top-layer of the Films | Polarity |
|---|---|---|
| Sample 1 | TiO2 | Hydrophobic |
| Sample 2 | TiO2-ZnO | Hydrophobic |
| Sample 3 | TiO2-ZnO-Cr/Au | some-what hydrophobic |
| Sample 4 | ZnO | Moderate Hydrophobic |
| Sample 5 | ZnO-Cr/Au | Moderate hydrophilic |
| Sample 6 | Cr/Au | Highly hydrophilic |
| Sample 7 | TiO2-Cr/Au | Moderate hydrophilic |
| Sample 8 | Quartz | Hydrophobic |

Generally, it is believed that more hydrophobic a surface, higher is the repulsive action against microbe. Besides, the good transmittance property of ZnO makes it a good option for applications such as display screens and other optical devices and applications.

Example 5: Autoclave experiment: A single ZnO layer was grown both on borofloat glass and Stainless Steel. The experimental conditions for ZnO deposition via ALD were as follows: Borofloat wafers and coupons of Stainless Steel were cleaned using piranha solutions. The deposition of ZnO was done as before. The process parameter used was 200° C. chamber temperature for a total of 580 cycles. The rate of deposition was 1.1 Angstroms/cycle. The thickness of the resulting coatings was verified using ellipsometry and the results are presented below (Table 10). The resultant thickness was around 66 nm.

TABLE 10
Validation using ellipsometry 5-point measurement

| Point | RI | Thickness (nm) | Goodness of Fit |
|---|---|---|---|
| 1 | 1.943 | 65.17 | 9.19 |
| 2 | | 65.87 | 9.80 |
| 3 | | 65.93 | 9.67 |
| 4 | | 65.93 | 9.50 |
| 5 | | 66.64 | 9.24 |
| Average | | 65.90 | |

Further the antimicrobial ability was tested as follows: Preparation of Test Carrier Inoculums: 10 μl vol. of approx. 1-5×106 CFU/ml of cell culture was applied on to the substrates which were placed individually into separate sterile plates. Further the SS substrate was allowed to dry in the incubator at 37 deg. for 10 min. After drying, this SS substrate was put into the 100 ml phosphate buffer; each sample was vortexed for 1 hour contact time, followed by adding it into neutralizer solution.

TABLE 11
Neutralizer test:

| | | | Test | % Recovery |
|---|---|---|---|---|
| Test | Particulars | Control | Results | of control |
| Test A | Sample + | 92 | 84 | 91.30 |
| Neutralizer | DENA + | | | |
| Effectiveness | Organisms | | | |
| Test B | DENA + | | 86 | 93.47 |
| Neutralizer | Organisms | | | |
| toxicity | | | | |
| Test C | Phosphate | | 87 | 94.56 |
| Test | buffer + | | | |
| Organisms | organisms | | | |
| Viability | | | | |

Further, it was placed into different sterile petri dishes and neutralizing media was poured into each SS substrate. Again, each sample was vortexed for 2 min to facilitate the release of the carrier load from the sample surface into neutralizing broth and then the analysis was performed. Their controls were plated with SCDA by taking 1 ml volume and the plates were incubated at 37 deg. for 48 hrs. After incubation the samples were analyzed, and the readings were recorded with the help of colony counter and interpreted the results. Autoclaving was done at 15 lbs pressure and 121° C. temperature for 15 minutes.

TABLE 12
Anti-microbial activity analysis of glass
material before and after autoclaving
Count observed

| | | | Antimicrobial |
|---|---|---|---|
| | | | activity in % |
| | | | When compared |
| | zero hr | 1 hr | with control |
| Glass with the | 37000 | 22000 | 84.29 |
| metal oxide coating | | | |
| Control glass | 110000 | 140000 | |
| sample | | | |
| After Autoclaving | | | |
| Count observed | | | |
| | | | When compared |
| | zero hr | 1 hr | with control |
| Glass with the | 45000 | 26000 | 83.75 |
| metal oxide coating | | | |
| Control sample | 120000 | 160000 | |

Similar experiments were conducted with SS as a base and the results were very promising in that the antimicrobial ability was imparted with even a thin layer of the metal oxide and which stayed intact in spite of autoclaving (Table 13).

TABLE 13
Anti-microbial activity analysis of SS
material before and after autoclaving
Count observed

| | | | Antimicrobial |
|---|---|---|---|
| | | | activity in % |
| | | | When compare |
| | zero hr | 1 hr | with control |
| SS with the | 3500 | 5400 | 95.85 |
| antimicrobial | | | |
| coating | | | |
| Control SS | 360000 | 130000 | |
| sample | | | |
| After Autoclaving | | | |
| Count observed | | | |
| | | | When compare |
| | zero hr | 1 hr | with control |
| SS with the | 4200 | 5600 | 95.69 |
| antimicrobial | | | |
| coating | | | |
| Control SS | 360000 | 130000 | |
| sample | | | |

The inference from the microbiology assay (Table 11) is that on these surfaces the results could be better if there were laminates and or multiple layers of coatings. Besides, ALD films being resistant to getting worn away as proven by the results before and after autoclaving, confirm that autoclaving did not disturb the coatings proving the mechanical stability (Tables 12 & 13). Autoclaving was done at 15 lbs pressure and 121° C. temperature for 15 minutes.

The methodology of anti-microbial coatings using the atomic layer deposition (ALD) in the present invention can be regarded as a special type of chemical vapor deposition (CVD), where the process consists of introducing a precursor gas that attaches to all surfaces of the article as a monolayer. Further, ultra-thin, biocompatible ALD coatings can yield hermetic encapsulation of the device/surfaces, with a fraction of film thickness compared to other coating methods and with superior film uniformity and conformality, ensuring pinhole-free coverage. It can enable the use of common base materials, e.g., plain glass and stainless steels instead of costly base materials. The thermal ALD of many other metals is challenging because of their very negative electrochemical potentials.

In accordance with advantages of the present invention as compared with the existing formulations, the present invention intends to provide a big change in the field of antimicrobial coating by composite vapor deposition techniques. Besides, strong reducing agents can facilitate low-temperature thermal ALD processes for several electropositive metals. For example, titanium and tantalum can be deposited from their respective metal chlorides and aluminum metal can be deposited using an aluminum dihydride precursor and AlCl3. The deposition of antimicrobial metal layers by ALD is also covered in this work, where the coatings are non-toxic and of non-sensitizing/inert nature.

As vapor phase deposition and especially ALD is an important method where thin, conformal, hermetic, non-toxic, aseptic coatings can be deposited. This would be useful for applications such as display screens, surgical tools and in the medical implants for instance. In the implants arena, microelectronics are being increasingly combined with miniaturized devices embedded into body parts such as the heart etc. and protecting these devices from the body environment is important for the smooth functioning of the device. Going forward this technology will be important also for orthopedic devices and for the medical and health-care industry in general.

### Technical Advantages

Hydrophobicity and Oleophobicity: Anti-stick in nature (as evidenced by increasing hydrophobicity). The coatings can be synthesized to repel micro-organisms by their intrinsic hydrophobic nature.

Non-reactive/inert surface, so can be used in variety of applications. The coatings were stable even after multiple cycles of autoclaving.

High temperature resistance: The metal oxides and metal layers are stable at high temperatures Oxidation protection: the layers impart an oxidation protection to the underlayers.

Corrosion resistance: The layers impart corrosion protection to the underlayers.

Wear & abrasion resistance: The coatings can be designed to impart excellent wear and abrasion resistance.

It will be further appreciated that functions or structures of a plurality of components or steps may be combined into a single component or step, or the functions or structures of one-step or component may be split among plural steps or components. The present invention contemplates all these combinations. Unless stated otherwise, dimensions and geometries of the various structures depicted herein are not intended to be restrictive of the invention, and other dimensions or geometries are possible. In addition, while a feature of the present invention may have been described in the context of only one of the illustrated embodiments, such feature may be combined with one or more other features of other embodiments, for any given application. It will also be appreciated from the above that the fabrication of the unique structures herein and the operation thereof also constitute methods in accordance with the present invention. The present invention also encompasses intermediate and end products resulting from the practice of the methods herein. The use of “comprising” or “including” also contemplates embodiments that “consist essentially of” or “consist of” the recited feature.

Although embodiments for the present invention have been described in language specific to structural features, it is to be understood that the present invention is not necessarily limited to the specific features described. Rather, the specific features and methods are disclosed as embodiments for the present invention. Numerous modifications and adaptations of the system/component of the present invention will be apparent to those skilled in the art, and thus it is intended by the appended claims to cover all such modifications and adaptations which fall within the scope of the present invention.

While this detailed description has disclosed certain specific embodiments for illustrative purposes, various modifications will be apparent to those skilled in the art which do not constitute departures from the spirit and scope of the following claims, and it is to be distinctly understood that the foregoing descriptive matter is to be interpreted merely as illustrative and not as a limitation.

1. A method of making nanolaminates by vapor deposition process, the method comprising:
depositing conformal atomic layers on a substrate on a chuck in a first chamber for chemical vapor deposition, wherein the depositing includes,
flowing a carrier gas and a purge gas in the first chamber,
setting temperature of the chuck and a heater in the first chamber, followed by stabilizing the chamber,
flowing the carrier gas and purge gas at a flow rate for coating the atomic layer,
passivating a surface of the substrate by pulsing a precursor 1 for a pulse time, followed by removing excess precursor 1 by purging with carrier gas,
pulsing a precursor 2 for a pulse time to complete the surface reaction in the first chamber, followed by removing excess precursor 2 by purging with carrier gas, wherein the passivating and pulsing form one monolayer and are repeated multiple times based on a thickness of the atomic layer, and
flowing the purge and carrier gases for purging the first chamber for removing by-products; and
transferring the substrate to a second chamber for coating a metal-based layer by physical vapor deposition on the substrate, wherein the transferring includes,
transferring a metal-containing material to be deposited on the substrate from a condensed phase in a target to a vapor phase by sputtering and evaporation, wherein the target is the source material to be deposited,
supersaturating the vapor phase in an inert atmosphere to promote condensation of the metal containing layer on the substrate, and
heating of substrate containing the nanolaminate under inert atmosphere, wherein the depositing and the transferring are performed based on the surface of the substrate and the property of nanolaminate.

2. The method of claim 1, wherein the passivating deposits at least a layer of material of at least one of tungsten, titanium, molybdenum, silicon, tantalum, nickel, zinc, copper, gold, chromium, yttria, and oxides, nitrides, and inorganic and organometallic compounds of the same.

3. The method of claim 1, wherein the precursor 1 or precursor 2 include at least one of a metal alkoxide, metal alkyl, metal diketonite, metal amindinate, metal carbonyl, metal chloride, organometallic, and organic-inorganic material.

4. The method of claim 3, wherein the precursor 1 or precursor 2 is at least one of: Mo, Ta and Ti deposited from a pentachloride; Ni, Mo, and W deposited at low temperature from a carbonyl precursor; Tetrakis titanium, diethyl zinc, and a materials that can form metal oxides; Pt, Ag, Au, and nitrides thereof; aliphatic or aromatic organic precursor having molecules with —OH, —COOH, —NH2, —CONH2, —CHO, —COCl, —SH, —CNO, or —CN, alkenes, functional groups, and oxidizers; and a reducer.

5. The method of claim 1, wherein at least one of the carrier gas and the purge gas is selected from a group of inert gases comprising argon, nitrogen, helium, and combinations thereof.

6. The method of claim 1, wherein the flow rate of the gases is 20 to 200 sccm.

7. The method of claim 1, wherein the heater temperature in the first and the second chamber is 16 to 250° C.

8. The method of claim 1, wherein the first and the second chamber are each an ultra-high vacuum chamber or an atmospheric chamber, and wherein the body of the first and the second chamber is made of aluminum, stainless steel, and combinations thereof.

9. The method of claim 1, wherein the pulse of the precursor 1 and the precursor 2 is given for 0.1 mS to 5 seconds.

10. The method of claim 1, wherein at least one of the conformal atomic layers and metal-based layers has a thickness from about 0.1 nm to about 200 nm.

11. The method of claim 1, wherein the physical vapor deposition is for depositing layers of metal containing titanium, titanium nitrate, tantalum, tantalum nitrate, compounds of metals such as copper, silver, gold, and combinations thereof, and derivatives of nitrides, oxide, carbide, boride.

12. The method of claim 1, wherein the sputtering includes bombarding the target with energetic inert gas to achieve a thin film vapor-phase deposition on the substrate.

13. The method of claim 1, wherein the evaporation of the target is conducted by resistive heating to an evaporation point using electrical energy to achieve the vapor-phase species that nucleates and deposits on the substrate.

14. The method of claim 1, wherein the supersaturating includes covering active sites on the substrate by a precursor of the material to make a fully reacted layer on the surface.

15. The method of claim 14, wherein the precursor of the material is entered into the chamber in the vapor phase and deposited by reacting with the substrate functionalities or the layer from the half-reactions.

16. The method of claim 1, wherein the chuck is heated to a temperature in the thermal treatment to aid the deposition process and yield a conformal coating of nanolaminates.

17. The method of claim 1, wherein the substrate for coating is a glass, soft polymeric materials, hard surface, or powder.

18. The method of claim 1, wherein the method creates at least one coating including a plurality of monolayers, wherein a first layer of material and a second layer of material for the coating have different characteristics, and wherein the coating is deposited using chemical vapor deposition or physical vapor deposition.

19. The method of claim 18, wherein the coating is created by chemical vapor deposition (CVD) and/or physical vapor deposition (PVD), wherein the CVD includes at least one of aerosol assisted CVD (AACVD) and deposition with self-assembled monolayers (SAM) with organic molecules using dip or spray to electrostatically charge the surface of the nanolaminates.

20. The method of claim 1, further comprising:
before deposition of a final layer, patterning the layers with lithography to impart a texture to repel microbes.
